(19) United States
(12) Patent Application Publication
(10) Pub. No.: US 2025/0280569 A1
(43) Pub. Date: Sep. 4, 2025

(54) Display Device

(71) Applicant: LG Display Co., Ltd., Seoul (KR)

(72) Inventors: Sun Young Choi, Paju-si (KR); Moon Ho Park, Paju-si (KR); Sung Jin Lee, Paju-si (KR)

(21) Appl. No.: 19/065,677

(22) Filed: Feb. 27, 2025

(30) Foreign Application Priority Data
Feb. 29, 2024 (KR) 10-2024-0029911

(51) Int. Cl. H10D 30/67; H10D 86/40; H10D 86/60; H10K 59/121

(52) U.S. Cl. CPC H10D 30/6737; H10D 30/6723; H10D 30/6743; H10D 30/6755; H10D 86/425; H10D 86/441; H10D 86/60; H10K 59/1213

(57) ABSTRACT

A display device includes a first transistor including a first light shielding pattern as a first metal layer, a first active layer overlapping the first light shielding pattern, a first gate electrode as a second metal layer, and a first-drain electrode as a third metal layer and connected to the first active layer, a second transistor including a second light shielding pattern spaced apart from the first source and drain electrodes and formed of the third metal layer, a second active layer overlapping the second light shielding pattern, a second gate electrode as a fourth metal layer, and second source and drain electrodes as a fifth metal layer and connected to the second active layer, and a first connection electrode as the third metal layer and connected to the first gate electrode and the first light shielding pattern.

### CROSS-REFERENCE TO RELATED APPLICATION

This application claims the benefit of Republic of Korea Patent Application No. 10-2024-0029911 filed on Feb. 29, 2024, which is hereby incorporated by reference in its entirety.

### BACKGROUND

### Field of Technology

The present disclosure relates to a display device, and more specifically, to a display device including a transistor that improves the effect of preventing or at least reducing hydrogen from moving to an adjacent transistor and improves on-current.

### Discussion of the Related Art

Display devices that display images in televisions, monitors, smartphones, tablets, and laptop computers are used in various manners and forms.

A display device includes a plurality of pixels for displaying an image, and a transistor for controlling the operation of each pixel.

A display device includes a plurality of pixels, and a plurality of driving and switching elements for driving and controlling the pixels. The driving and switching elements may be configured as transistors, and transistors are widely applied not only to pixels but also to integrated circuits.

Recently, various research and development have been conducted to improve the performance and reliability of transistors.

### SUMMARY

Accordingly, the present disclosure is directed to a display device that substantially obviates one or more problems due to limitations and disadvantages of the related art.

An object of embodiments of the present disclosure is to provide a display device capable of preventing or at least reducing hydrogen from moving to a transistor including an oxide semiconductor by changing the structure of a transistor adjacent to the transistor including an oxide semiconductor.

Another object of the embodiments of the present disclosure is to provide a display device capable of minimizing a falling time or a rising time until on time by connecting gate electrodes of at least some of transistors having a switching function and a light shielding pattern in a structure in which heterogeneous transistors are disposed.

Another object of the embodiments of the present disclosure is to provide a display device capable of reducing the size of transistors having dual gates and implementing a narrow bezel by applying the transistors to a gate-in-panel.

Another object of the embodiments of the present disclosure is to provide a light emitting display device having a hydrogen shielding structure formed without an additional mask or material by arranging a source-drain electrode of a first transistor using a hydrogen-capturing metal included in a second transistor when the first transistor including crystalline silicon is disposed adjacent to the second transistor including an oxide semiconductor.

Another object of the embodiments of the present disclosure is to minimize a falling time and improve on-time characteristics by connecting gate electrodes of at least some of transistors to which an emission control signal is applied and a light shielding pattern, thereby improving the reliability of device operation without hindering turn-on operations of adjacent transistors.

Another object of the embodiments of the present disclosure is to provide a display device having a sufficient sampling time margin by minimizing a falling time until the on time of a transistor and securing a sufficient on-time operation period.

The present disclosure can improve the hydrogen shielding characteristics of transistors by changing the structure of the transistors and use an electrode of an adjacent transistor as a hydrogen shielding metal layer without adding a process. Accordingly, the amounts of materials used in the manufacturing process, such as gases and etching solutions for manufacturing the display device, can be reduced. Therefore, greenhouse gases generated due to the manufacturing process can be reduced and a light emitting display device can be provided through process optimization.

A display device according to an embodiment of the present disclosure includes a first transistor provided on a substrate and including a first light shielding pattern as a first metal layer, a first active layer overlapping the first light shielding pattern, a first gate electrode as a second metal layer and partially overlapping the first active layer, and a first source-drain electrode as a third metal layer and connected to the first active layer, a second transistor provided on the substrate and including a second light shielding pattern spaced apart from the first source-drain electrodes and as the third metal layer, a second active layer overlapping the second light shielding pattern, a second gate electrode as a fourth metal layer and partially overlapping the second active layer, and a second-drain electrodes as a fifth metal layer and connected to the second active layer, and a first connection electrode as the third metal layer and connected to the first gate electrode and the first light shielding pattern.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic plan view showing a display device according to an embodiment of the present disclosure;

FIG. 2 is a circuit diagram showing a sub-pixel according to an embodiment of the present disclosure;

FIG. 3 is a circuit diagram showing a configuration of a gate-in-panel according to an embodiment of the present disclosure;

FIG. 4 is a circuit diagram showing a sub-pixel according to another embodiment of the present disclosure;

FIG. 5 is a plan view showing a fifth transistor in FIG. 4 according to an embodiment of the present disclosure;

FIG. 6 is a cross-sectional view along line I-I′ of FIG. 5 according to an embodiment of the present disclosure;

FIG. 7 is a cross-sectional view along line II-II′ of FIG. 5 according to an embodiment of the present disclosure;

FIG. 8 is a cross-sectional view showing various types of transistors according to an embodiment of the present disclosure;

FIG. 9 is a timing diagram for comparison of on-time periods of an emission control signal with respect to transistors having different mobilities in active layers; and

FIG. 10 is a cross-sectional view showing the display device according to an embodiment of the present disclosure.

### DETAILED DESCRIPTION

Hereinafter, preferred embodiments of the present disclosure will be described with reference to the attached drawings. In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted. In addition, the names of elements used in the following description are selected in consideration of clarity of description of the specification and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings. In the present disclosure, where terms such as “including,” “having,” “comprising,” and the like are used, one or more components can be added, unless the term, such as “only,” is used. The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

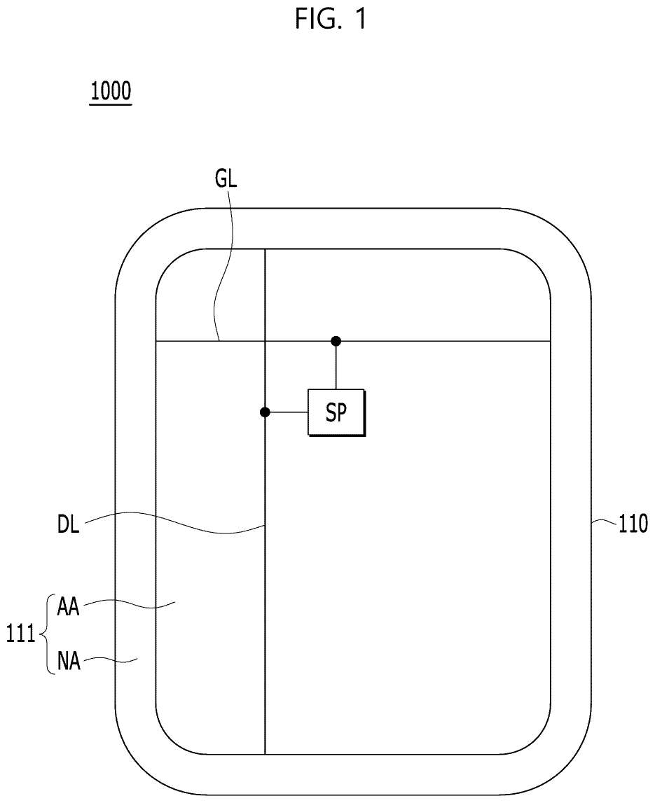

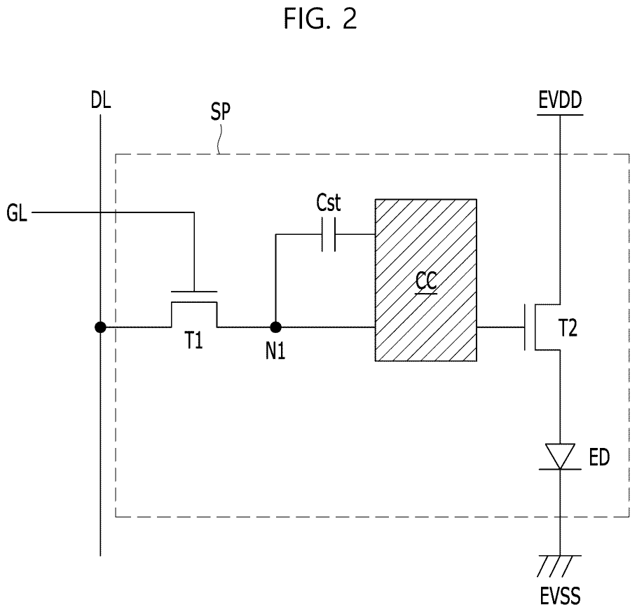

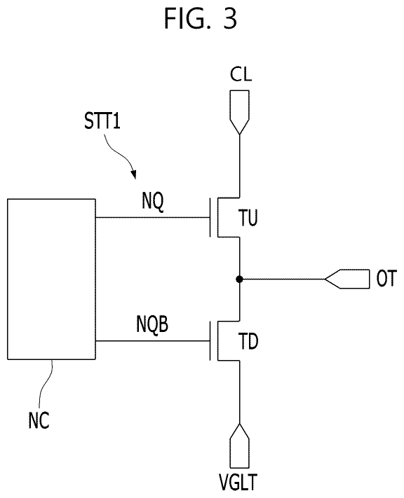

FIG. 1 is a schematic plan view showing a display device according to an embodiment of the present disclosure. FIG. 2 is a circuit diagram showing a sub-pixel according to an embodiment of the present disclosure. FIG. 3 is a circuit diagram showing a configuration of a gate-in-panel (a gate-in panel driver) according to an embodiment of the present disclosure.

Referring to FIG. 1 and FIG. 2, a display device 1000 according to an embodiment of the present disclosure may include a display panel 110 and a case (not shown) for accommodating a side surface and a lower part of the display panel 110. A non-active area NA of the display panel 110 may be covered by the case or by a separate light shielding film. A printed circuit film and/or a battery may be provided between the bottom of the display panel 110 and the case.

The display panel 110 may include a substrate 111 including an active area AA and a non-active area NA surrounding the active area AA, and a driving unit connected to the substrate 111. The driving unit may be formed together with an array provided at the active area AA by being integrated into the substrate 111, may be connected to the substrate 111 in a Chip On Glass (COG) structure, or may be connected to a printed circuit board through a film or a connector in a Chip On Film (COF) structure on the substrate 111. Alternatively, the driving unit may include components integrated into the substrate 111 and an external component of the COG or COF.

The active area AA is an area in which an image is displayed. A plurality of sub-pixels SP are disposed at the active area AA of the display panel 110 and an image can be displayed using the plurality of sub-pixels SP. An area other than the active area AA may be the non-active area NA.

The non-active area NA may be disposed in an edge area surrounding the active area AA for displaying an image. At least one driving unit for driving the plurality of sub-pixels SP may be disposed in the non-active area NA. The driving unit may include a gate-in-panel GIP. The gate-in-panel GIP is connected to a plurality of gate lines GL at the active area AA and may sequentially supply a gate voltage signal to the plurality of gate lines GL.

Various additional elements for driving the sub-pixels SP at the active area AA may be further disposed in the non-active area NA.

At least one of the plurality of sub-pixels SP may include a first transistor T1, a second transistor T2, a storage capacitor Cst, a compensation circuit CC, and a light emitting element ED, as illustrated in FIG. 2.

For example, the first transistor T1 may be a switching transistor, and the second transistor T2 may be a driving transistor.

A first electrode (e.g., a drain electrode) of the first transistor T1 is electrically connected to a data line DL, and a second electrode (e.g., a source electrode) thereof is electrically connected to a first node N1. A gate electrode of the first transistor T1 is electrically connected to a gate line GL. The first transistor T1 transmits a data signal supplied through the data line DL to the first node N1 in response to a scan signal supplied through the gate line GL.

The storage capacitor Cst is electrically connected to the first node N1 and charged with a voltage applied to the first node N1.

A first electrode (e.g., a drain electrode) of the second transistor T2 may be connected to a voltage line which a high-potential driving voltage EVDD is supplied, and a second electrode (e.g., a source electrode) thereof may be electrically connected to a first electrode (e.g., an anode) of the light emitting element ED. The second transistor T2 can control the amount of driving current flowing through the light emitting element ED in response to the voltage difference between the gate electrode and the source electrode.

A semiconductor layer of the first transistor T1 or/and the second transistor T2 may include amorphous silicon (a-Si), polysilicon, or low temperature polysilicon, or may include an oxide semiconductor.

In the display device of the embodiments of the present disclosure, at least one of transistors formed on the substrate 111 includes an oxide semiconductor material. The oxide semiconductor material can be formed at a relatively low temperature compared to other materials, maintains amorphous characteristics, and has high mobility.

The light emitting element ED emits light corresponding to a driving current. The light emitting element ED may emit light corresponding to one of colors of red, green, blue, and white.

The light emitting element ED may include an anode, an intermediate layer disposed on the anode, and a cathode supplying a common voltage. The intermediate layer includes at least one emission layer and may be formed to emit light of the same color, such as white light, for pixels or may be formed to emit light of different colors, such as red, green, and blue lights, for respective sub-pixels SP when an electric field is formed between the anode and the cathode. The intermediate layer may include various types of common layers and functional layers in addition to the emission layer to efficiently supply holes and electrons to the emission layer.

The light emitting element ED may be a front emitting diode or a back emitting diode.

The compensation circuit CC may be additionally provided within the sub-pixel SP to compensate for the threshold voltage of the second transistor T2. The compensation circuit CC may be composed of one or more transistors. The compensation circuit CC may include one or more transistors and capacitors and may be configured in various manners depending on the compensation method. The sub-pixel SP including the compensation circuit CC may include circuits of various structures having different numbers of transistors and/or capacitors, such as 3T1C, 4T2C, 5T2C, 6TIC, 6T2C, 7T1C, and 7T2C.

Among the transistors provided in the sub-pixel, the switching transistor may be required to operate at a high speed for fast switching operation. The driving transistor may be required to output a high current to the light emitting element for expression with high luminance.

The gate-in-panel GIP included in the non-active area NA outputs gate signals to gate lines according to a gate control signal input from a timing controller, for example. The gate-in-panel GIP may include a plurality of transistors, and the plurality of transistors may be formed through the same process as the transistors of the sub-pixel SP.

For example, the gate-in-panel GIP may include stages STT1 that are connected in a cascade manner, as shown in FIG. 3, and the stages STT1 may sequentially output gate signals to the gate lines.

Each of the stages STT1 includes, as shown in FIG. 3, a pull-up node NQ, a pull-down node NQB, a pull-up transistor TU that is turned on when the pull-up node NQ is charged with a gate high voltage, a pull-down transistor TD that is turned on when the pull-down node NQB is charged with the gate high voltage, and a node controller NC for controlling charging and discharging of the pull-up node NQ and the pull-down node NQB.

The node controller NC can be connected to a start signal line to which a start signal or a carry signal of a previous stage is input, and a clock line to which one of gate clock signals is input. The node controller NC controls charging and discharging of the pull-up node NQ and the pull-down node NQB according to the start signal or the carry signal of the previous stage input to the start signal line and the gate clock signal input to the clock line. The node controller discharges the pull-down node NQB to a gate low voltage when the pull-up node NQ is charged with the gate high voltage and discharges the pull-up node NQ to the gate low voltage when the pull-down node NQB is charged with the gate high voltage in order to stably control the output of the stage STT1. To this end, the node controller NC may include a plurality of transistors.

The pull-up transistor TU is turned on when the stage STT1 is pulled up, that is, when the pull-up node NQ is charged with the gate high voltage, and outputs the gate clock signal applied through the clock line CL to an output terminal OT. The pull-down transistor TD is turned on when the stage STT1 is pulled down, that is, when the pull-down node NQB is charged with the gate high voltage and discharges the output terminal OT to the gate low voltage of a gate low voltage terminal VGLT.

In FIG. 3, the plurality of transistors including the pull-up transistor TU, the pull-down transistor TD, and the node controller NC of each stage STT1 of the gate-in-panel GIP may be required to output the gate high voltage and to have high response speed. To this end, crystalline silicon having excellent mobility characteristics may be included in the active layer, or an active layer made of a high-mobility oxide semiconductor may be used.

Although an example in which the plurality of transistors including the transistors T1 and T2 of the sub-pixel SP, and the pull-up transistor TU, the pull-down transistor TD, and the node controller NC of each stage STT1 of the gate-in-panel GIP are N-type semiconductor transistors having N-type semiconductor characteristics is illustrated in FIG. 2 and FIG. 3, the embodiments of the present disclosure are not limited thereto. That is, at least one of the plurality of transistors including the pull-up transistor TU, the pull-down transistor TD, and the node controller NC of each stage STT1 of the gate in panel may be a P-type semiconductor transistor having P-type semiconductor characteristics.

The display panel 110 may be provided with a data driver in addition to the gate-in-panel GIP. For example, the data driver may include at least one source drive integrated circuit (hereinafter referred to as an “IC”). The source drive IC receives digital video data and a source control signal from the timing controller. The source drive IC converts the digital video data into analog data voltages according to the source control signal and provides the same to data lines DL.

In a case where the source drive IC is formed as a driving chip such as an integrated circuit, the source drive IC may be mounted on a flexible film in a COF structure. Wires connecting pads and the source drive IC, and wires connecting pads and wires of a circuit board are formed on the flexible film. The flexible film is attached onto pads such as data pads formed in the non-active area NA of the display panel DP using an anisotropic conductive film, thereby connecting the pads and the wires of the flexible film.

The active layers of the transistors are formed as oxide semiconductor layers, thereby omitting high-temperature crystallization and having a certain level of mobility or higher. In addition, recent display devices have been formed by including an oxide semiconductor layer that allows a high-temperature crystallization process to be omitted and has the advantage of easy material accessibility in consideration of environmental pollution caused by high-temperature crystallization processes.

Hereinafter, a structure of a display device including a first transistor including crystalline silicon, which is applicable to transistors of sub-pixels SP and transistors of a gate-in-panel GIP of the display device requiring high-speed operation due to high resolution, and a second transistor adjacent to the first transistor and using an oxide semiconductor as an active layer according to an embodiment of the present disclosure will be described in detail.

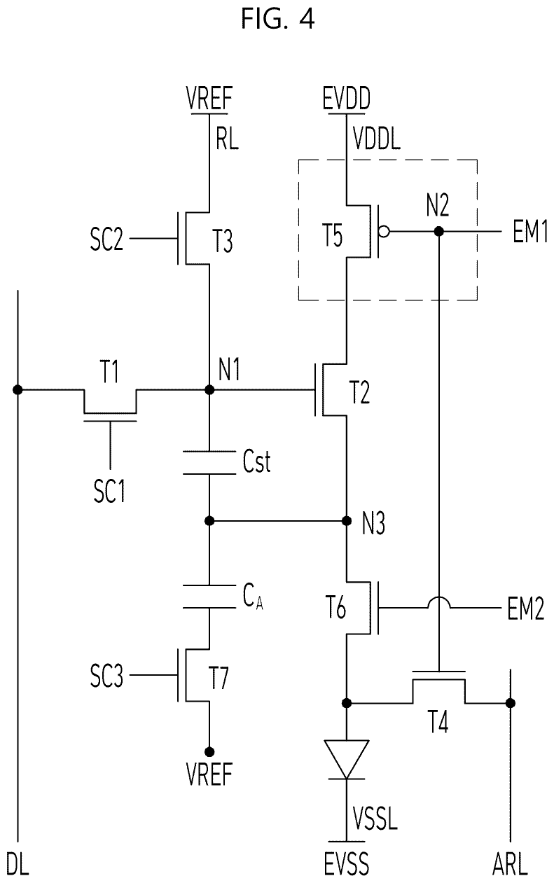

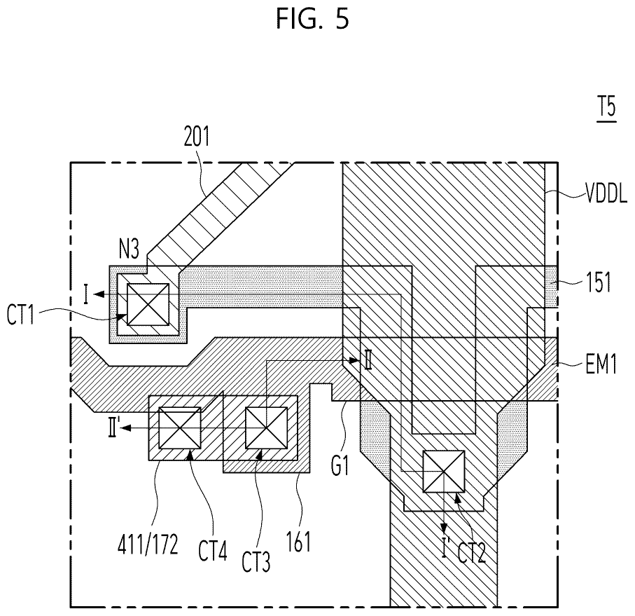

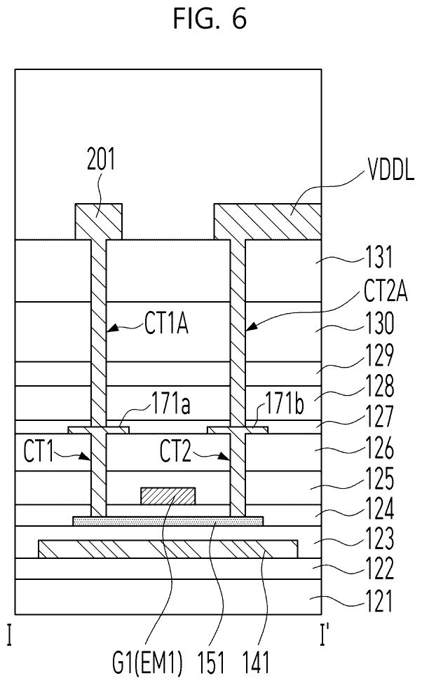

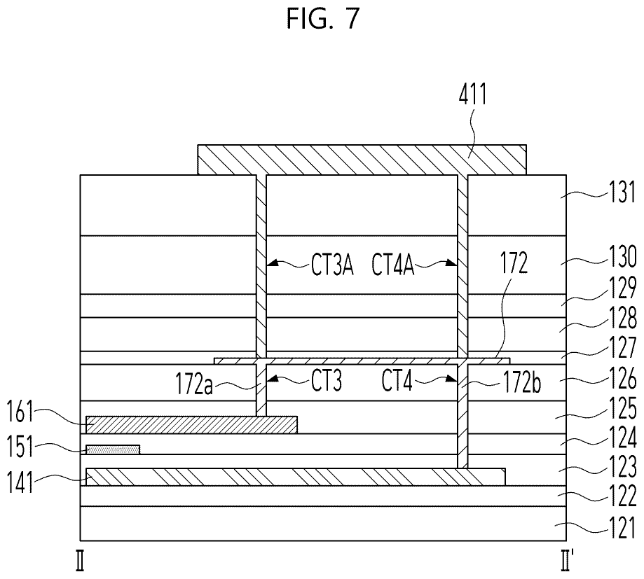

FIG. 4 is a circuit diagram showing a sub-pixel according to another embodiment of the present disclosure. FIG. 5 is a plan view showing a fifth transistor in FIG. 4 according to an embodiment of the present disclosure. FIG. 6 is a cross-sectional view along line I-I′ of FIG. 5 according to an embodiment of the present disclosure. FIG. 7 is a cross-sectional view along line II-II′ of FIG. 5 according to an embodiment of the present disclosure.

As shown in FIG. 4, the sub-pixel according to another embodiment of the present disclosure is further connected to a plurality of scan lines SC1, SC2, and SC3, first and second emission control lines EM1 and EM2, an anode reset signal line ARL, and a reference voltage line RL to operate a light emitting element ED more finely compared to FIG. 2.

Referring to FIG. 4, the sub-pixel according to another embodiment of the present disclosure includes a first transistor T1 to a seventh transistor T7, a storage capacitor Cst, a compensation capacitor CA, and a light emitting element ED.

The first transistor T1 has a gate electrode connected to the first scan line SC1 and a drain electrode connected to a data line DL. A first node N1 serving as a source electrode of the first transistor T1 is connected to a gate electrode of the second transistor T2. The gate electrode of the second transistor T2 is connected to the first node N1, and a source electrode thereof is connected to a third node N3. The storage capacitor Cst is provided between the first node N1 and the third node N3 serving as the source electrode of the second transistor T2. The third transistor T3 has a gate electrode connected to the second scan line SC2, a drain electrode connected to the reference voltage line RL, for example, and a source electrode connected to the first node N1. The fourth transistor T4 has a gate electrode connected to the first emission control line EM1, a drain electrode connected to the anode reset signal line ARL, and a source electrode connected to the anode of the light emitting element ED. The fifth transistor T5 has a gate electrode connected to the first emission control line EM1 and is disposed between a first power voltage line VDDL through which the high-potential driving voltage EVDD is supplied and the second transistor T2. For example, the drain electrode of the fifth transistor T5 is connected to the first power voltage line VDDL through which the high-potential driving voltage EVDD is supplied, and the source electrode thereof is connected to the drain electrode of the second transistor T2. A second node N2 serving as the gate electrode of the fifth transistor T5 may be connected to the fourth transistor T4 to which a same emission control signal is applied by the first emission control line EM1. The sixth transistor T6 has a gate electrode connected to the second emission control line EM2, a drain electrode connected to the third node N3 serving as the second electrode of the second transistor T2, for example, and a source electrode connected to the anode of the light emitting element ED. The compensation capacitor CA and the seventh transistor T7 are connected in series between the third node N3 and the reference voltage line RL through which a reference voltage VREF is supplied. The seventh transistor T7 has a gate electrode connected to the third scan line SC3, a drain electrode connected to one electrode of the compensation capacitor CA, for example, and a source electrode connected to the reference voltage line RL.

In FIG. 4, the fifth transistor T5 is illustrated as a PMOS, and the remaining transistors are illustrated as NMOSs. The fifth transistor T5 is connected in series with the second transistor T2, the sixth transistor T6, and the light emitting element ED, and has a long gate-on time period, which directly affects the serially connected components, and thus the fifth transistor T5 may be vulnerable to positive bias stress PBS. Therefore, it may be more preferable to configure the fifth transistor T5 as a PMOS in which a low signal is applied as a gate-on signal to offset the positive bias stress. However, the embodiments of the present disclosure are not limited thereto.

The first transistor T1, the third transistor T3, the fourth transistor T4, the sixth transistor T6, and the seventh transistor T7 are turned on when a gate high voltage is applied to the gate electrodes thereof, and the fifth transistor T5 is turned on when a low voltage is applied through the first emission control line EM1.

The second transistor T2 functions as a driving transistor by generating a driving current when the first transistor T1 and the fifth transistor T5 are turned on and transferring the driving current to the third node N3.

The second transistor T2 functions as a driving transistor capable of representing various grayscales, and the first transistor T1 and the third to seventh transistors T3, T4, T5, T6, and T7 may function as switching transistors requiring high-speed operation.

The first to third scan signals can be sequentially applied through the first to third scan lines, respectively, and operations of the first transistor T1, the third transistor T3, and the seventh transistor T7 may be optional. In a normal driving state, the first transistor T1 operates in a turned-on state, receives a data voltage, transfers the same to the first node N1, and can turn on the second transistor T2 that supplies the driving current. In the turn-on state of the third transistor T3 and the seventh transistor T7, the potentials of the first node N1 and the third node N3 can be compensated using the reference voltage VREF.

When a data signal is supplied to the first node N1 to turn on the second transistor T2, and a low voltage is supplied as the emission control signal to the fifth transistor T5 to turn on the fifth transistor T5, the driving current generated in the second transistor T2 is transmitted to the third node N3 through the fifth transistor T5 and the second transistor T2 that are turned on by the high-potential driving voltage EVDD, and then the driving current can be transmitted to the anode of the light emitting element ED according to a high voltage supplied through the second emission control line EM2. The fourth transistor T4 is connected to the anode reset signal line ARL and is turned on whenever an anode reset signal VAR is supplied to initialize the voltage applied to the anode of the light emitting element ED.

The anode of the light emitting element ED is connected to the fourth transistor T4 and the sixth transistor T6, and the cathode thereof is connected to a second power voltage line VSSL through which a low-potential driving voltage EVSS is supplied. The voltage of the anode of the light emitting element ED can be initialized according to the turn-on operation of the fourth transistor T4, and the driving current generated by the second transistor T2 can be supplied to the anode of the light emitting element ED according to the turn-on operation of the sixth transistor T6.

When the anode reset voltage VAR is applied to the anode of the light emitting element ED, the light emitting element ED is initialized, and when the driving current is applied to the anode of the light emitting element ED, the light emitting element ED emits light.

In the display device of the embodiments of the present disclosure, the low-potential driving voltage EVSS may be set to be lower than the high-potential driving voltage EVDD.

Each light emitting element OLED can display one of the colors of white, red, green, and blue.

As shown in FIG. 4, in an on-time operation period of the fifth transistor T5, the high-potential driving voltage EVDD can be transmitted to the second transistor T2 connected to the fifth transistor T5 in a state in which both the second transistor T2 and the sixth transistor T6 connected in series with the fifth transistor T5 are turned on.

Therefore, a falling operation to the gate low voltage needs to be performed before the second transistor T2 and the sixth transistor T6 are turned on in order not to interfere with the turn-on operations the second transistors T2 or sixth transistors T6, and accordingly, the falling operation to the gate voltage needs to have no delay.

In the display device according to an embodiment of the present disclosure, the active layer of the fifth transistor T5 is made of, for example, crystalline silicon having higher mobility than an oxide semiconductor to enable a fast falling operation, and the active layer of the remaining first to fourth transistors T1, T2, T3, and T4 and sixth and seventh transistors T6 and T7 having multiple functions are formed to have an active layer made of an oxide semiconductor of the same layer ns, thereby optimizing the process and improving the optical reliability of the active layer.

As shown in FIG. 5 to FIG. 7, the fifth transistor T5 in FIG. 4 is provided on a substrate 121, and includes a first light shielding pattern 141 formed from a first metal layer, a first active layer 151 overlapping the first light shielding pattern 141, and a first gate electrode G1 and a gate connection electrode 161 partially overlapping the first active layer 151, formed from a second metal layer, and integrated with the first emission control line EM1 through which the emission control signal is supplied.

In addition, the fifth transistor T5 includes first source-drain electrodes 171a and 171b as a third metal layer and connected to the first active layer 151. The first source-drain electrodes 171a and 171b include a first electrode 171a and a second electrode 171b and are connected to both sides of the upper surface of the first active layer 151, which are spaced apart from each other.

The fifth transistor T5 may be formed from the third metal layer and may include a first connection electrode 172 connected to the first gate electrode G1 and the first light shielding pattern 141.

The gate connection electrode 161 integrated with the first emission control line EM1 is connected to the first light shielding pattern 141 through the first connection electrode 172, and thus a gate voltage of the same potential is applied into first emission control line EM, the gate connection electrode 161 and the first light shielding pattern 141, in the fifth transistor T5. The first emission control line EM1 and the first gate electrode G1 are integrated with each other. Accordingly, the fifth transistor T5 has a dual gate, and since the first gate electrode G1 and the first light shielding pattern 141 have a dual switching function with respect to the first active layer 151, the falling operation of the gate voltage of the emission control signal can be performed at a high speed. Therefore, adjacent transistors are turned on in an on-time period of the emission control signal, and thus the operations of the adjacent transistors are not affected. This means that there is no delay in falling and rising operations during turn-on/turn-off and that the switching operation can be performed at a high speed without interference.

In addition, the fifth transistor T5 can secure a sufficient sampling time margin since the on current increases due to the dual gate structure.

The upper portions of the first electrode 171a and the second electrode 171b may be connected to a first cover electrode 201 and the first power voltage line VDDL formed to overlap the first and second electrodes 171a and 171b, respectively. The first cover electrode 201 may be extended from one side and connected to the first electrode (e.g., the drain electrode) of the second transistor T2.

The first electrode 171a and the second electrode 171b are formed of a material including a hydrogen-capturing metal. For example, the hydrogen-capturing metal may be a metal including titanium (Ti) having excellent hydrogen capturing capability. For example, the first electrode 171a and the second electrode 171b may be a single titanium layer, a double layer of molybdenum (Mo) and titanium (Ti), or an alloy of molybdenum (Mo) and titanium (Ti). The first electrode 171a and the second electrode 171b may also be other metal layers including titanium (Ti).

The first electrode 171a and the second electrode 171b have a hydrogen capture function, and thus can shield adjacent transistors including an oxide semiconductor layer as an active layer from hydrogen.

A transistor including an oxide semiconductor layer as an active layer can be affected not only by diffusion of impurities introduced during a process of doping impurities into the active layer, but also by hydrogen that diffuses toward the transistor array from an encapsulation layer for protecting light emitting elements after aging of insulating films or formation of the light emitting elements.

The display device according to an embodiment of the present disclosure does not have source-drain electrodes at a same layer as the first power voltage line VDDL, and the first and second electrodes 171a and 171b are as a third metal layer having a hydrogen capture characteristic and adjacent to the first gate electrode 161. The first and second electrodes 171a and 171b are positioned adjacent to an insulating film under the active layers of adjacent transistors including an oxide semiconductor. The first and second electrodes 171a and 171b capture hydrogen or other gas which are directly transmitted or penetrate through insulating films for the oxide semiconductor active layers, thereby can improve the reliability of the transistors including the oxide semiconductor active layers.

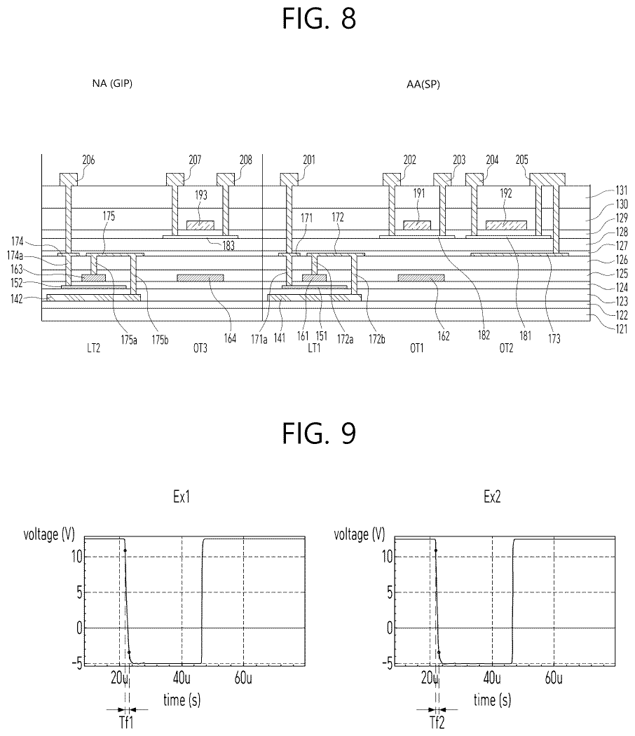

As described with reference to FIG. 4, the transistors included in the sub-pixel can be divided into the fifth transistor T5 using polysilicon for the first active layer 151, and the first to fourth transistors T1 to T4 and the sixth and seventh transistors T6 and T7 which use an oxide semiconductor for the active layers (181 and 182 in FIG. 8). In addition, these transistors T1 to T7 may be provided adjacently at each sub-pixel on the substrate 121.

The fifth transistor T5 is provided on the substrate. The substrate may comprise a flexible plastic material and thus can have flexibility. As another example, the substrate 121 may include a thin glass material having flexibility.

As an example, the substrate 121 may comprise first and second organic films overlapping each other with an inorganic interlayer insulating film therebetween. The first and second organic films may include different organic films of the same or different types, such as polyethylene terephthalate (PET) and polyimide. In some cases, an adhesive film of, for example, a pressure sensitive adhesive (PSA) may be included between the first and second organic films.

The substrate 121 serves to support and protect components of the display device 1000 disposed thereon.

A plurality of insulating films 122, 123, 124, 125, 126, 127, 128, 129, 130, 131, 132, and 133 may be laminated on the active area AA and the non-active area (NA in FIG. 1) of the substrate 121 such that the electrodes of different metal layers of transistors can be insulated from each other.

A buffer layer 122 on the substrate 121 is made of an inorganic insulating material and is disposed on the active area AA and the non-active area NA of the substrate 121. The buffer layer 122 is formed on the substrate 121 to protect structures disposed on the substrate 121 from moisture penetrating through the substrate 121 and to planarize the surface of the substrate 121.

The buffer layer 122 may be formed to extend to the edge of the substrate 121 to prevent or at least reduce moisture from penetrating from the edge of the substrate 121. The buffer layer 122 may be used as a buffer layer for the first active layer 151 included in the fifth transistor disposed on the substrate 121.

In some cases, the buffer layer 122 may comprise a plurality of inorganic films.

For example, the buffer layer 122 may include one or more inorganic films from among a silicon oxide (SiOx) film, a silicon nitride (SiNx) film, and a silicon oxynitride (SiOxNy) film, or may include a multilayer in which the inorganic films described above are laminated.

The first light shielding pattern 141 may be made of a conductive metal material and disposed on the buffer layer 122. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

A first insulating film 123 may be provided on the buffer layer 122 on which the first light shielding pattern 141 is disposed. The first insulating film 123 may serve as a buffer layer for the first active layer 151.

The first insulating film 123 may include an inorganic material film. The inorganic material film may include, for example, a silicon oxide (SiOx) film, a silicon nitride (SiNx) film, or multiple layers thereof.

The first active layer 151 is disposed on the first insulating film 123 to overlap the first light shielding pattern 141. The first active layer 151 closest to the substrate 121 may contain crystalline silicon. The mobility of the first active layer 151 may be higher than the mobility of the active layers of adjacent transistors.

The first active layer 151 may intersect and partially overlap the first emission control line EM1 disposed in a first direction, for example, as shown in FIG. 5, and the region partially overlapping the first emission control line EM1 can be defined as a channel of an intrinsic region.

A second insulating film 124 is provided on the first insulating film 123 on which the first active layer 151 is disposed.

The second insulating film 124 may include an inorganic material film. The inorganic material film may include, for example, a silicon oxide (SiOx) film, a silicon nitride (SiNx), or multiple layers thereof. The second insulating film 124 may be used as a gate insulating film of the fifth transistor.

The first emission control line EM1 is disposed across the first active layer 151 on the second insulating film 124. Referring to FIG. 5, the first emission control line EM1 is disposed, for example, in the first direction, and includes the first gate electrode G1 integrated therewith and overlapping the first active layer 151 and the gate connection electrode 161 that protrudes from the first emission control line EM1 and does not overlap the first active layer 151.

The first emission control line EM1 is made of a conductive metal material. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

A third insulating film 125 and a fourth insulating film 126 are sequentially disposed on the second insulating film 124 on which the first emission control line EM1 including the first gate electrode G1 and the gate connection electrode 161 is disposed. The third and fourth insulating films 125 and 126 may be used as interlayer insulating films for the fifth transistor T5.

The third and fourth insulating films 125 and 126 may include an inorganic insulating film. The inorganic insulating film may include, for example, a silicon oxide (SiOx) film, a silicon nitride (SiNx) film, or multiple layers thereof.

As shown in FIG. 6, the first electrode 171a and the second electrode 171b connected to both sides of the upper surface of the first active layer 151 through first and second contact holes CT1 and CT2 penetrating the second to fourth insulating films 124, 125, and 126, and the first connection electrode 172 connected to the first gate connection electrode 161 through a third contact hole CT3 penetrating the third and fourth insulating films 125 and 126 and connected to the first light shielding pattern 141 through a fourth contact hole CT4 penetrating the first to fourth insulating films 123, 124, 125, and 126 comprise a hydrogen-capturing metal on the fourth insulating film 126.

The first connection electrode 172 may include a first vertical connection portion 172a filling the third contact hole CT3 provided in the third and fourth insulating films 125 and 126, and a second vertical connection portion 172b filling the fourth contact hole CT4 provided in the first to fourth insulating films 123, 124, 125, and 126. As shown in FIG. 7, the second vertical connection portion 172b may be spaced apart from and adjacent to the first active layer 151.

The vertical distance of the second vertical connection portion 172b of the first connection electrode 172 is longer than the vertical distance of the first vertical connection portion 172a.

The first connection electrode 172 connects the first gate connection electrode 161 and the first light shielding pattern 141 and also has a function of capturing hydrogen remaining in portions of the insulating films 123, 124, 125, and 126 adjacent to the second vertical connection portion 172b that vertically penetrating the first to fourth insulating films 123, 124, 125, and 127.

The first and second electrodes 171a and 171b serve as a source electrode or a drain electrode of the first transistor LT1. The first and second electrodes 171a and 171b comprise a metal layer having hydrogen capture characteristics, and the first and second electrodes 171b and 171b are horizontally positioned adjacent to other transistors including oxide semiconductors at the sub-pixel, and thus the fifth transistor T5 can capture hydrogen, etc. which is directly transmitted or penetrates through insulating films for the oxide semiconductor active layers, thereby improving the reliability of the transistors including the oxide semiconductor as the active layers.

The first and second electrodes 171a and 171b can be used as one electrode along with the light shielding pattern in the transistors T1, T2, T3, T4, T6, and T7 including oxide semiconductor, and thus can be formed together with the transistors T1, T2, T3, T4, T6, and T7 including oxide semiconductor when the transistors T1, T2, T3, T4, T6, and T7 are formed without adding a process. Therefore, process optimization can be achieved.

The light emitting display device according to the embodiments of the present disclosure can solve defects such as threshold voltage change and on/off defects that occur when hydrogen remains in insulating films by capturing hydrogen included in the insulating films using the source-drain electrode of the transistor. In addition, the transistor to which the emission control signal is applied has a dual-gate structure to improve the on current and reduce falling time and rising time, thereby achieving high-speed operation. Furthermore, when a transistor having an active layer different from a transistor including an oxide semiconductor, the metal layer used in the transistor including the oxide semiconductor is used as the source-drain electrode, thereby enabling connection between the active layer and the gate connection electrode and the light shielding pattern without adding a mask. Accordingly, the amount of materials used in the manufacturing process, such as gases and etching solutions, to manufacture the display device can be reduced. Therefore, it is possible to provide a light emitting display device that enables process optimization and reduces greenhouse gases generated due to the manufacturing process. In addition, the display device according to the embodiments of the present disclosure can reduce the number of processes required to process additional materials for each area, decrease production energy, and reduce emission of greenhouse gases that may be generated due to the manufacturing process through process optimization. Therefore, ESG (Environmental/Social/Governance) goals can be achieved through process optimization.

The first light shielding pattern 141 and the first gate electrode 162 are connected by the gate connection electrode 174 and thus have the same potential. Accordingly, the first light shielding pattern 141 and the first gate electrode 162 may be used as gates (e.g., gate electrodes) under and above the first active layer 152. Therefore, the first transistor T1 includes a dual gate, has high-speed operation characteristics, and has a dual switching function, and thus it is easy to integrate and dispose the first transistor T1 in a limited area.

The conductive metal material forming the source-drain electrode 171, a first connection electrode 172, and a second light shielding pattern 173 and the gate connection electrode 174 may include at least one of an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

Fifth to ninth insulating films 127, 128, 129, 130, and 131 are sequentially provided on the fourth insulating film 126 on which the source-drain electrodes 171 and 174, a first connection electrode 172, and a second light shielding pattern 173 and the gate connection electrode 175 are disposed, and contact holes CT1A and CT2A are formed in the fifth to ninth insulating films 127, 128, 129, 130, and 131 such that the first electrode 171a and the second electrode 171b are exposed. The contact holes CT1A and CT2A provided in the fifth to ninth insulating films 127, 128, 129, 130, and 131 may overlap the first and second contact holes CT1 and CT2, but the present disclosure is not limited thereto. Contact holes CT3A and CT4A are formed in the fifth to ninth insulating films 127, 128, 129, 130, and 131 to expose a part of the first connection electrode 172 in the same process.

FIG. 7 shows an example in which two contact holes CT3A and CT4A exposing a part of the first connection electrode 172 are provided corresponding to the third and fourth contact holes CT3 and CT4, but the embodiments of the present disclosure are not limited thereto. A single contact hole may be provided in the fifth to ninth insulating films 127, 128, 129, 130, and 131 to expose the first connection electrode 172, and in this case, the contact hole may overlap the third contact hole CT3 or the fourth contact hole CT4 and may also expose another part of the first connection electrode 172.

The fifth to ninth insulating films 127, 128, 129, 130, and 131 may be used as a buffer layer, a gate insulating film, an interlayer insulating film, etc. of transistors including oxide semiconductors adjacent to the fifth transistor T5.

The first cover electrode 201 and the first power voltage line VDDL may be connected to the first electrode 171a and the second electrode 171b through the contact holes CT1A and CT2A formed in the fifth to ninth insulating films 127, 128, 129, 130, and 131.

Hereinafter, examples of transistors including an oxide semiconductor, which are formed on the substrate adjacent to the fifth transistor T5, will be described.

FIG. 8 is a cross-sectional view showing various types of transistors according to an embodiment of the present disclosure.

In FIG. 8, transistors including crystalline silicon are referred to as LT1 and LT2, and transistors including an oxide semiconductor are referred to as OT1, OT2, and OT3.

FIG. 8 shows a first transistor LT1 that functions as a switching transistor and has a first active layer containing crystalline silicon, a second transistor OT2 that functions as a driving transistor and contains an oxide semiconductor as a second active layer, and a third transistor OT1 that functions as a switching transistor and contains an oxide semiconductor as a third active layer, which are disposed at each sub-pixel of the active area AA.

In FIG. 8, the non-active area NA represents a part of the gate-in-panel GIP. The gate-in-panel GIP of the non-active area NA may include a first type transistor LT2 that functions as a switching transistor and a buffer transistor and includes a first active layer containing crystalline silicon, and a second type transistor OT3 that functions as a switching transistor and includes an oxide active layer.

The configuration of the first transistor LT1 is the same as the configuration of the fifth transistor T5 described with reference to FIG. 5 to FIG. 7.

More specifically, the first transistor LT1 may be provided on the buffer layer 122 on the substrate 121. That is, the first transistor LT1 may serve as the fifth transistor T5 of the circuit of FIG. 4.

The first transistor LT1 includes the first light shielding pattern 141 as a first metal layer, the first active layer 151 overlapping the first light shielding pattern 141, the first gate electrode G1 and the gate connection electrode 161 integrated with the first emission control line EM1 as a second metal layer and partially overlapping the first active layer 151, through which an emission control signal is supplied.

In addition, the first transistor LT1 includes the first source-drain electrodes 171 (171a and 171b) as a third metal layer and connected to the first active layer 151. The first electrode 171a and the second electrode 171b of the first source-drain electrode are separately connected to both sides of the upper surface of the first active layer 151.

Further, the first transistor LT1 may include a first connection electrode 172 as the third metal layer and connected to the first gate electrode G1 and the first light shielding pattern 141.

The first electrode 171a of the first source-drain electrode 171 may be connected to the first cover electrode 201.

The second transistor OT2 may be provided on the fourth insulating film 126 on the substrate 121. The second transistor OT2 may be spaced apart from the first source-drain electrode 171 of the first transistor LT1.

The second transistor OT2 may include a second light shielding pattern 173 as the third metal layer, a second active layer 181 overlapping the second light shielding pattern 173, a second gate electrode 192 as a fourth metal layer and partially overlapping the second active layer 181, and second source-drain electrode 204 and 205 as a fifth metal layer and connected to the second active layer.

The second transistor OT2 includes the second light shielding pattern 173 formed on the fourth insulating film 126 on the substrate 121. The second transistor OT2 may be spaced apart from the first source-drain electrodes 171 of the first transistor LT1.

The second light shielding pattern 173 is made of a hydrogen-capturing metal and is formed through the same process as the process of forming the first source-drain electrodes 171a and 171b of the adjacent first transistor LT1.

The second light shielding pattern 173 can prevent or at least reduce hydrogen from moving to the second active layer 181 overlapping the second light shielding pattern 173, and the first source-drain electrodes 171a and 171b of the first transistor LT1 can prevent hydrogen from moving to the adjacent second active layer 181.

The first electrode 204 of the second source-drain electrodes 204 and 205 is connected to one side of the upper surface of the second active layer 181, and the second electrode 205 is disposed to be spaced apart from the first electrode 204 with the second gate electrode 192 interposed therebetween and includes a first vertical connection portion 205a connected to the second active layer 181 and a second vertical connection portion 205b connected to the second light shielding pattern 173. The same voltage is applied to the second light shielding pattern 173 and the second electrode 205 of the second transistor OT2, and thus the potential is stabilized.

The third transistor OT1 having a light shielding pattern formed on a different layer from the second transistor OT2 will be described.

The third transistor OT1 may be provided at each of the plurality of sub-pixels of the substrate. The third transistor OT1 may be any one of the first transistor T1, the third transistor T3, the fourth transistor T4, the sixth transistor T6, and the seventh transistor T7 in the circuit of FIG. 4.

The third transistor OT1 may include a third light shielding pattern 162 as the second metal layer, a third active layer 182 overlapping the third light shielding pattern, a third gate electrode 191 as the fourth metal layer and partially overlapping the third active layer 182, and third source-drain electrodes 202 and 203 as the fifth metal layer and connected to the third active layer, which are formed on the substrate 121.

The third source-drain electrodes 202 and 203 may include a first electrode 202 connected to one side of the upper surface of the third active layer 182 and a second electrode 203 connected to the other side of the upper surface.

The third light shielding pattern 162 of the third transistor OT1 is located on the same layer as the first gate electrode 161 of the first transistor LT1 and thus can be formed through the same process as the process of forming the first and second transistors LT1 and OT2 without using an additional mask.

Meanwhile, the second active layer 181 and the third active layer 182 of the second and third transistors OT2 and OT1 are made of an oxide semiconductor. For example, the oxide semiconductor material may be made of an oxide of a metal such as zinc (Zn), indium (In), gallium (Ga), tin (Sn), or titanium (Ti), or a combination of a metal such as zinc (Zn), indium (In), gallium (Ga), tin (Sn), or titanium (Ti) and an oxide thereof.

More specifically, the oxide semiconductor material forming the second active layer 181 and the third active layer 182 may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), etc.

The second transistor OT2 and the third transistor OT1 can reduce power consumption according to improved leakage current blocking effect obtained by containing the oxide semiconductor material in the second active layer 181 and the third active layer 182.

The first transistor LT1 may further include the cover electrode 201 covering the first source-drain electrodes 171a and 171b, and a third connection electrode (411 in FIG. 7) connected to the first power voltage line VDDL and the first connection electrode 172, which are as the fifth metal layer of the same layer as the second and third source-drain electrodes 204, 205, 202, and 203 of the second transistor OT2 and the third transistor OT1. The third connection electrode 411 may be omitted in some cases.

The first type transistor LT2 provided in the gate-in-panel GIP may have the same configuration as the first transistor LT1 described above.

The second type transistor OT3 provided in the gate-in-panel GIP may have the same configuration as the third transistor OT1 described above.

That is, the first type transistor LT2 includes a first light shielding pattern 142 as the first metal layer, a first active layer 152 overlapping the first light shielding pattern 142, and a first gate electrode 163 as the second metal layer and partially overlapping the first active layer 152.

In addition, the first type transistor LT2 includes source-drain electrodes 174 as the third metal layer and connected to the first active layer 152.

Further, the first type transistor LT2 may include a first connection electrode 175 as the third metal layer and connected to the first gate electrode 163 and the first light shielding pattern 142.

The first active layer 152 of the first type transistor LT2 may comprise crystalline silicon disposed on the same layer as the first active layer 151 of the first transistor LT1 in the sub-pixel.

The first electrode 174a of the source-drain electrodes 174, which is connected to one side of the upper surface of the first active layer 152, may be connected to a second cover electrode 206.

The first type transistor LT2 has a dual gate structure in which the first gate electrode 163 and the first light shielding pattern 142 are connected and thus have the same potential, and they serve as gates above and under the first active layer 152.

Therefore, in the gate-in-panel GIP, the first type transistor has the effect of increasing the on-state current due to the dual gate structure, and both the width and length of the active layer channel of the transistor with the same output can be reduced, thereby minimizing the space occupied by the transistors in the gate-in-panel GIP, achieving a narrow bezel.

The second type transistor OT3 may be provided at the gate-in-panel GIP of the substrate. The second type transistor OT3 has a same structure as the third transistor OT1. The third transistor OT1 may be any one of the first transistor T1, the third transistor T3, the fourth transistor T4, the sixth transistor T6, and the seventh transistor T7 in the circuit of FIG. 4.

The second type transistor OT3 may include, on the substrate 121, a light shielding pattern 164 as the second metal layer, an oxide active layer 183 overlapping the light shielding pattern 164, a gate electrode 193 as the fourth metal layer and partially overlapping the oxide active layer 183, and third source-drain electrodes 207 and 208 as the fifth metal layer and connected to the oxide active layer 183.

The source-drain electrodes 207 and 208 may include a first electrode 207 connected to one side of the upper surface of the oxide active layer 183 and a second electrode 208 connected to the other side of the upper surface.

The light shielding pattern 164 of the second type transistor OT3 is located on the same layer as the first gate electrode 163 of the first type transistor LT2, and thus can be formed through the same process as the process for forming the transistors LT1, OT1, and OT2 of the sub-pixels without using an additional mask.

The second light shielding pattern 173 is made of a hydrogen-capturing metal and is formed through the same process as the process of forming the first source-drain electrodes 171a and 171b of the adjacent first transistor LT1.

The second light shielding pattern 173 can prevent or at least reduce hydrogen from moving to the second active layer 181 overlapping with the second light shielding pattern 173, and the first source-drain electrodes 171a and 171b of the first transistor LT1 can prevent hydrogen from moving to the adjacent second active layer 181.

The transistors are adjacent within the sub-pixel, and thus the first source-drain electrode 171 and the first connection electrode 172 included in the first transistor LT1 capture hydrogen under the second active layer 181 and the third active layer 182 to aid in preventing movement of hydrogen moving to the second and third transistors OT2 and OT1.

In the gate-in-panel GIP, the first type transistor LT2 with high mobility is adjacent to the second type transistor OT3 including an oxide semiconductor, and thus the first source-drain electrodes 174 and the first connection electrode 175 included in the first type transistor LT2 can prevent hydrogen from moving to the second type transistor OT3.

FIG. 9 is a timing diagram for comparison of on-time periods of an emission control signal with respect to transistors having different mobilities in active layers.

Referring to FIG. 9, a first experimental example Ex1 in which active layer mobility is set to approximately 10 cm²/Vs and a second experimental example Ex2 in which active layer mobility is set to 50 cm²/Vs are applied to the fifth transistor T5 in FIG. 4 and falling times Tf1 and Tf2 until reaching the low voltage are compared.

The falling time Tf1 is approximately 1.2991 us in the first experimental example Ex1 with low mobility, and the falling time Tf2 is approximately 1.0042 us in the second experimental example Ex2 with high mobility. That is, it can be ascertained that the falling time decreases as the active layer mobility increases.

If the falling time increases, it may interfere with the turn-on timing of an adjacent transistors, and thus the adjacent transistors may operate in a state in which the sufficient gate low voltage is not applied, which may deteriorate the operational reliability of each transistor. In the display device according to the embodiments of the present disclosure, the first transistor LT1 in the sub-pixels and the first type transistor LT2 in the gate-in-panel are formed using crystalline silicon with high mobility in a dual gate structure to minimize the falling time and increase the on-current value.

When display devices operate with high reliability at a high temperature, component deterioration may occur, falling time may increase, and a sampling timing interval may decrease. In the display device according to the embodiment of the present disclosure, high-mobility crystalline silicon is used for transistors that perform sampling, such as the first transistor LT1 in the sub-pixels and the first type transistor LT2 in the gate-in-panel, and a dual-gate structure is applied thereto to minimize or at least reduce the falling time even during operation with high reliability at a high temperature, thereby improving operational reliability without interfering with the operations of adjacent transistors.

In the gate-in-panel GIP, the first type transistor LT2 operating at a high speed and having a high on-current value can be arranged more densely than the second type transistor OT3 to achieve high-speed operation.

In addition, the first type transistor LT2 arranged with high density in the gate-in-panel GIP can prevent hydrogen from moving to the second type transistor OT3 and perform a protective function.

The mobility of crystalline silicon is generally higher than that of oxide semiconductors. In the display device according to the embodiment of the present disclosure, as shown in FIG. 8, the first transistor LT1 in the sub-pixel and the first type transistor LT2 in the gate-in panel, which require high-speed operation, have a dual-gate structure in which the gate electrode and the light shielding pattern are connected, and thus the operation speed is high and the falling time is reduced, enabling high-speed operation. Accordingly, the on period is increased by a reduction in the falling time, and sufficient sampling time can be secured.

In the display device according to the embodiment of the present disclosure, the first transistor LT1 in the sub-pixel and the first type transistor LT2 in the gate-in-panel have a dual-gate structure, and thus the on current can increase. Therefore, even if the channel size (W/L) of the active layer is reduced, on-current characteristics equivalent to or higher than those of a single-gate structure can be obtained, and accordingly, the degree of integration can be increased for the same output, achieving a narrow bezel.

Hereinafter, a display device according to an embodiment of the present disclosure will be described.

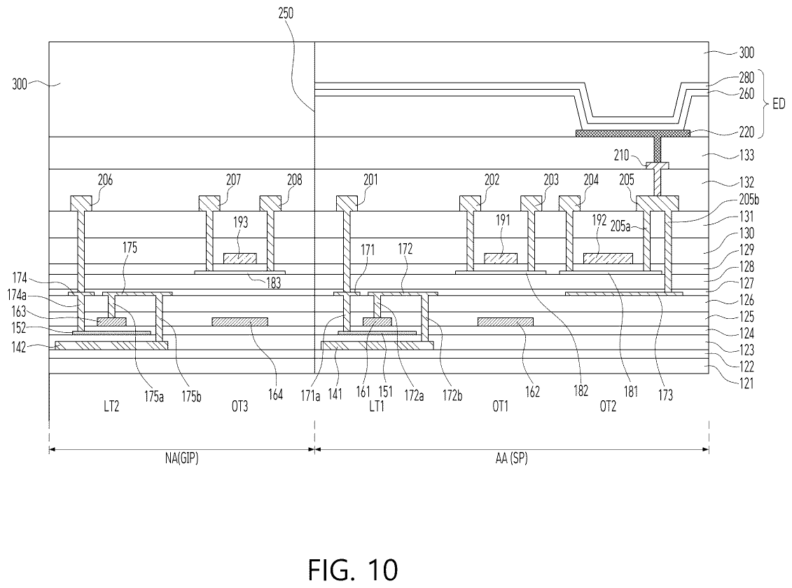

FIG. 10 is a cross-sectional view showing a display device according to an embodiment of the present disclosure.

In FIG. 10, description of the structure in the display device according to an embodiment of the present disclosure as that in FIG. 8 will be omitted.

As shown in FIG. 10, a first planarization film 132 may be provided to cover the source-drain electrodes 204, 205, 202, 203, 207, and 208 and the cover electrodes 201 and 206 and to protect the transistors disposed thereunder.

The first planarization film 132 may include an organic material. The organic material may include one or more of an acrylic resin, a phenolic resin, a polyimide resin, an unsaturated polyester resin, a polyamide resin, a benzocyclobutene, a polyphenylene resin, or a polyphenylene sulfide resin.

The first planarization film 132 includes a contact hole exposing a portion of the upper portion of the second source/drain electrode 205 of the second transistor OT2, and a second connection electrode 210 is further provided through the contact hole to be connected to the second source/drain electrode 205. The second source-drain electrode 205 may be as a second source-drain metal layer or a sixth metal layer.

Additionally, a second planarization film 133 covering the second connection electrode 210 may be further provided.

The second planarization film 133 may include an organic material. The organic material may include at least one of an acrylic resin, a phenolic resin, a polyimide resin, an unsaturated polyester resin, a polyamide resin, a benzocyclobutene, a polyphenylene resin, or a polyphenylene sulfide resin.

The second planarization film 133 includes a contact hole, and an anode 220 connected to the second connection electrode 210 may be further provided through the contact hole.

The anode 220, a cathode 280 facing the anode 220, and an intermediate layer 260 between the anode 220 and the cathode 280 form a light emitting element ED.

One of the anode 220 and the cathode 280 may include a reflective electrode, and the other may include a transparent electrode or a reflective-transparent electrode.

When the anode 220 includes a reflective electrode, the anode 220 may function to shield light incident on the transistor (TFT) disposed there below. The anode 220 may be formed, for example, in a laminated structure of a first transparent electrode, a reflective electrode, and a second transparent electrode. The second transparent electrode, which is the uppermost electrode of the anode 220, can lower a barrier for hole injection at the interface with the intermediate layer 260 as a dielectric. Here, the first and second transparent electrodes may be transparent oxide electrodes such as ITO and IZO. The reflective electrode may include silver, a silver alloy such as APC (Ag—Pd—Cu), aluminum, or an aluminum alloy.

For example, the anode 220 may be formed in a multilayer structure such as a laminated structure (Ti/Al/Ti) of aluminum (Al) and titanium (Ti), a laminated structure (ITO/Al/ITO) of aluminum (Al) and ITO, an APC (Ag/Pd/Cu) alloy, a laminated structure (ITO/APC/ITO) of an APC alloy and ITO, and a laminated structure (Ag/MoTI) of silver (Ag) and molybdenum/titanium alloy, or may have a single-layer structure made of one material selected from silver (Ag), aluminum (Al), molybdenum (Mo), gold (Au), magnesium (Mg), calcium (Ca), or barium (Ba), or two or more alloy materials.

A pixel defining film 250 is disposed to surround the edge of the anode 220, and a light emitting area may be defined in an open area of the pixel defining film.

The pixel defining film 250 may include an inorganic material or an organic material. The pixel defining film 250 may include an opaque material (e.g., black) to prevent optical interference between adjacent sub-pixels (SP). In this case, the pixel defining film 250 may include a light shielding material which is at least one of a color pigment, organic black, or carbon.

The intermediate layer 260 may include a hole injection layer, a hole transport layer, an emission layer, an electron transport layer, and an electron injection layer. The intermediate layer 260 may be formed in a tandem structure in which a plurality of stacks including a hole transport layer, an emission layer, and an electron transport layer is formed, and a charge generation layer is provided between the stacks. The charge generation layer may include, for example, an n-type charge generation layer and a p-type charge generation layer.

The emission layer included in the intermediate layer 260 may include different emission layers for respective sub-pixels. The emission layer EML may include a red emission layer that emits red light, a green emission layer that emits green light, and a blue emission layer that emits blue light. The red emission layer, the green emission layer, and the blue emission layer may be arranged for respective sub-pixels SP on the anode 220.

For example, the red emission layer may be patterned and disposed in a red sub-pixel, the green emission layer may be patterned and disposed in a green sub-pixel, and the blue emission layer may be patterned and disposed in a blue sub-pixel. The present disclosure is not necessarily limited thereto, and at least two or more organic emission layers among the red emission layer, the green emission layer, and the blue emission layer may be laminated and disposed in one sub-pixel SP.

The emission layer EML included in the intermediate layer may be a white emission layer that emits white light. In this case, the emission layer EML may be in the form of a common layer in which one or more layers are commonly disposed in the sub-pixels SP, instead of the form of a pattern.

As described above, the emission layer included in the intermediate layer may be arranged in a tandem structure of two or more stacks. In this case, each light emitting element ED may include a charge generation layer disposed between the stacks. The charge generation layer may be a common layer disposed on the entire surface of the active area AA.

The cathode 280 may comprise a thin transparent electrode such as ITO or IZO, or a thin reflective transparent electrode such as silver, a silver alloy, magnesium, a magnesium alloy, ytterbium (Yb), or an ytterbium alloy. In another embodiment, in order to increase the transmittance in a transparent area TA, the cathode 280 may be partially removed or formed to be thin in the transparent area TA. The cathode 280 may be a common layer that is commonly disposed in the sub-pixels SP and applies the same voltage. For this purpose, the cathode 280 may be provided to extend from the active area AA to a part of the non-active area NA.

The cathode 280 may be a light transmitting electrode. The cathode 280 may include a transparent conductive oxide (TCO) such as ITO or IZO that can transmit light, or a semi-transmissive conductive material such as magnesium (Mg), silver (Ag), or an alloy of magnesium (Mg) and silver (Ag). When the cathode 280 comprises a semi-transmissive metal material, the light emission efficiency can be increased according to the microcavity effect.

Although a front-emitting type has been described as an example of a light emitting element ED, the light emitting element ED of the present disclosure is not limited thereto and may be a back-emitting type in which light emitted from the intermediate layer 260 is emitted toward the substrate 121. In this case, the anode 220 may comprise a transparent or translucent electrode material, and the cathode 280 may be comprise a reflective electrode material.

An encapsulation layer 300 is disposed on the light emitting element ED. The encapsulation layer 300 may cover the active area AA and the non-active area NA to prevent or at least reduce oxygen or moisture from penetrating into the light emitting element ED. Other layers, such as a capping layer, may be interposed between the encapsulation layer 300 and the cathode 280 as needed.

The encapsulation layer 300 may be composed of a plurality of layers. The encapsulation layer 300 may be formed in a structure in which an inorganic film including an inorganic insulating material and an organic film including an organic insulating material are alternately laminated. For example, the inorganic insulating material may include one or more materials such as silicon oxide, silicon nitride, and silicon oxynitride.

The organic insulating material may include one or more materials selected from the group consisting of polyethylene terephthalate, polyethylene naphthalate, polycarbonate, polyimide, polyethylene sulfonate, polyoxymethylene, polyarylate, and hexamethyldisiloxane.

A capping layer may be further formed on the cathode 280 to protect the cathode 280 of the light emitting element ED and increase the efficiency of light emission upward.

A display device according to one embodiment of the present disclosure may comprise a first transistor on a substrate, the first transistor including a first light shielding pattern as a first metal layer, a first active layer overlapping the first light shielding pattern, a first gate electrode as a second metal layer partially overlapping the first active layer, and a first source-drain electrode as a third metal layer connected to the first active layer, a second transistor on the substrate, the second transistor including a second light shielding pattern as the third metal layer spaced apart from the first source-drain electrode, a second active layer overlapping the second light shielding pattern, a second gate electrode as a fourth metal layer partially overlapping the second active layer, and a second source-drain electrode as a fifth metal layer connected to the second active layer and a first connection electrode as the third metal layer, the first connection electrode connected to the first gate electrode and the first light shielding pattern.

In a display device according to one embodiment of the present disclosure, the first connection electrode may include a first vertical connection portion penetrating an insulating film between the third metal layer and the second metal layer, and a second vertical connection portion penetrating an insulating film between the third metal layer and the first metal layer. The second vertical connection portion may be adjacent to the first active layer.

In a display device according to one embodiment of the present disclosure, a vertical distance of the second vertical connection portion may be longer than a vertical distance of the first vertical connection portion.

In a display device according to one embodiment of the present disclosure, the third metal layer may include a hydrogen-capturing metal.

In a display device according to one embodiment of the present disclosure, the first active layer may include crystalline silicon, and the second active layer may include an oxide semiconductor.

In a display device according to one embodiment of the present disclosure, the first active layer may have a higher mobility than the second active layer.

A display device according to one embodiment of the present disclosure may further comprise at least one first silicon oxide film between the third metal layer and the second active layer; and at least one second silicon oxide film between the second active layer and the second gate electrode.

In a display device according to one embodiment of the present disclosure, the first transistor and the second transistor may be provided adjacent to each other at each of a plurality of sub-pixels of the substrate.

In a display device according to one embodiment of the present disclosure, an emission control signal may be applied to the first gate electrode.

In a display device according to one embodiment of the present disclosure, the second source-drain electrode may include a first vertical connection portion connected to the second active layer and a second vertical connection portion connected to the second light shielding pattern. The second vertical connection portion may be deeper than the first vertical connection portion and may be horizontally spaced apart from the second active layer.

A display device according to one embodiment of the present disclosure may further comprise a third transistor at each of the plurality of sub-pixels, the third transistor including a third light shielding pattern as the second metal layer, a third active layer overlapping the third light shielding pattern, a third gate electrode as the fourth metal layer partially overlapping the third active layer, and a third source-drain electrode as the fifth metal layer connected to the third active layer.

In a display device according to one embodiment of the present disclosure, a scan signal may be applied to the third gate electrode.

In a display device according to one embodiment of the present disclosure, the second active layer and the third active layer may be disposed at a same layer and include an oxide semiconductor.

In a display device according to one embodiment of the present disclosure, the first transistor and the second transistor may be adjacent to each other and may be provided at a gate-in-panel disposed in a non-active area surrounding the plurality of sub-pixels of the substrate.

In a display device according to one embodiment of the present disclosure, an arrangement density of the first transistor may be greater than an arrangement density of the second transistor in the gate-in-panel.

A display device according to one embodiment of the present disclosure may further comprise a first cover electrode as the fifth metal layer over the first source-drain electrode, the first cover electrode connected to the first source-drain electrode.

In a display device according to one embodiment of the present disclosure, the second transistor is electrically connected to a light emitting element.

In a display device according to one embodiment of the present disclosure, the light emitting element may include an anode, an intermediate layer, and a cathode. A second connection electrode as a sixth metal layer may be provided between the anode and the second source-drain electrode, and the second connection electrode may be located above the fifth metal layer.

In the display device according to the embodiments of the present disclosure, the structure of a transistor adjacent to a transistor including an oxide semiconductor can be changed to prevent hydrogen from moving to the transistor including an oxide semiconductor.

In the display device according to embodiments of the present disclosure, a falling time or a rising time until the on time can be minimized by connecting the gate electrodes of at least some of the transistors having a switching function to a light shielding pattern.

In the display device according to the embodiments of the present disclosure, the size of transistors having dual gates can be reduced, and the transistors can be applied to a gate-in-panel to achieve a narrow bezel.

In the display device according to the embodiments of the present disclosure, a hydrogen shielding structure can be formed without adding a separate mask or material by arranging the first transistor including crystalline silicon and the second transistor including an oxide semiconductor adjacently and forming the source-drain electrode of the first transistor using a hydrogen-capturing metal included in the second transistor.

In the display device according to the embodiments of the present disclosure, the falling time is minimized and the on-time characteristics are improved by connecting the gate electrode and the light shielding pattern in at least some of the transistors to which the emission control signal is applied, thereby not hindering the turn-on operations of adjacent transistors and improving device operational reliability.

In the display device according to the embodiments of the present disclosure, the falling time until the on-time of the transistor is minimized and a sufficient on-time driving period is secured, and thus a display device having a sufficient sampling time margin can be provided.

In the display device according to the embodiments of the present disclosure, power consumption can be reduced by increasing on current using the structure in which the gate electrode of the transistor and the light shielding pattern are connected.

The display device according to the embodiments of the present disclosure has a sufficient sampling time margin by minimizing the falling time until reaching the on-current time and securing a sufficient on-time driving period and has high efficiency.

The display device according to the embodiments of the present disclosure can improve the hydrogen shielding characteristics of transistors by changing the structure of the transistors and can use the electrode of an adjacent transistor as a hydrogen shielding metal layer without adding a process. Accordingly, the amounts of materials used in the manufacturing process, such as gases and etching solutions for manufacturing the display device, can be reduced. Therefore, greenhouse gases generated due to the manufacturing process can be reduced, and process optimization can be achieved.

The display device according to the embodiments of the present disclosure can prevent or at least reduce hydrogen from moving to a transistor including oxide semiconductor by changing the structure of a transistor adjacent to the transistor including oxide semiconductor.

The display device according to the embodiments of the present disclosure can minimize the falling time or rising time until the on time by connecting gate electrodes of at least some of transistors having a switching function and a light shielding pattern in the structure in which heterogeneous transistors are disposed.

The display device according to the embodiments of the present disclosure can reduce the size of transistors having dual gates and can implement a narrow bezel by applying the transistors to a gate-in-panel.

The display device according to the embodiments of the present disclosure can achieve a hydrogen shielding structure without adding a separate mask or material by arranging the source-drain electrodes of the first transistor using a hydrogen-capturing metal included in the second transistor when the first transistor including crystalline silicon is disposed adjacent to the second transistor including an oxide semiconductor.

The display device according to the embodiments of the present disclosure can improve the reliability of element operation by minimizing the falling time and improving the on-time characteristics by connecting the gate electrodes of at least some of transistors to which the emission control signal is applied and a light shielding pattern to prevent the turn-on operations of adjacent transistors from being hindered.

The display device according to the embodiments of the present disclosure can provide a display device having a sufficient sampling time margin by minimizing the falling time until the on-time of a transistor and securing a sufficient on-time operation period.

The display device according to the embodiments of the present disclosure has the advantage of being able to reduce power consumption by improving the on-current using a structure in which the gate electrode of a transistor and a light shielding pattern are connected.

The embodiments of the present disclosure can provide a display device having a sufficient sampling time margin by minimizing the falling time until on time and securing a sufficient on-time operation period driving and can secure high efficiency.

The display device according to the embodiments of the present disclosure has a modified transistor structure, and thus the hydrogen shielding characteristics of transistors can be improved and electrodes of an adjacent transistor can be used as a hydrogen shielding metal (layer) without an additional process. Therefore, the amounts of materials used in the manufacturing process, such as gases and etching solutions for manufacturing the display device, can be reduced. Accordingly, greenhouse gases generated during the manufacturing process can be reduced and process optimization can be achieved.

It will be apparent to those skilled in the art that various modifications and variations can be made in the present disclosure without departing from the spirit or scope of the disclosure. Thus, it is intended that the present disclosure covers the modifications and variations of the disclosure provided they come within the scope of the appended claims and their equivalents.

What is claimed is:

1. A display device comprising:
a first transistor on a substrate, the first transistor including a first light shielding pattern as a first metal layer, a first active layer overlapping the first light shielding pattern, a first gate electrode as a second metal layer that partially overlaps the first active layer, and a first source-drain electrode as a third metal layer that is connected to the first active layer;
a second transistor on the substrate, the second transistor including a second light shielding pattern as the third metal layer and being spaced apart from the first source-drain electrode, a second active layer overlapping the second light shielding pattern, a second gate electrode as a fourth metal layer that partially overlaps the second active layer, and a second source-drain electrode as a fifth metal layer that is connected to the second active layer; and
a first connection electrode as the third metal layer, the first connection electrode connected to the first gate electrode and the first light shielding pattern.

2. The display device of claim 1, wherein the first connection electrode includes a first vertical connection portion penetrating an insulating film that is between the third metal layer and the second metal layer, and a second vertical connection portion penetrating an insulating film that is between the third metal layer and the first metal layer,
wherein the second vertical connection portion is adjacent to the first active layer.

3. The display device of claim 2, wherein a vertical distance of the second vertical connection portion is longer than a vertical distance of the first vertical connection portion.

4. The display device of claim 1, wherein the third metal layer includes a hydrogen-capturing metal.

5. The display device of claim 1, wherein the first active layer includes crystalline silicon and the second active layer includes an oxide semiconductor.

6. The display device of claim 1, wherein the first active layer has a mobility that is higher than a mobility of the second active layer.

7. The display device of claim 1, further comprising:
at least one first silicon oxide film that is between the third metal layer and the second active layer; and
at least one second silicon oxide film that is between the second active layer and the second gate electrode.

8. The display device of claim 1, wherein the first transistor and the second transistor are adjacent to each other at each of a plurality of sub-pixels of the substrate.

9. The display device of claim 8, wherein an emission control signal is applied to the first gate electrode.

10. The display device of claim 1, wherein the second source-drain electrode includes a first vertical connection portion that is connected to the second active layer and a second vertical connection portion that is connected to the second light shielding pattern,
wherein the second vertical connection portion is deeper than the first vertical connection portion and is horizontally spaced apart from the second active layer.

11. The display device of claim 8, further comprising:
a third transistor at each of the plurality of sub-pixels, the third transistor including a third light shielding pattern as the second metal layer, a third active layer overlapping the third light shielding pattern, a third gate electrode as the fourth metal layer that partially overlaps the third active layer, and a third source-drain electrode as the fifth metal layer that is connected to the third active layer.

12. The display device of claim 11, wherein a scan signal is applied to the third gate electrode.

13. The display device of claim 11, wherein the second active layer and the third active layer are at a same layer and include an oxide semiconductor.

14. The display device of claim 8, wherein the first transistor and the second transistor are adjacent to each other and are at a gate-in-panel disposed in a non-active area surrounding the plurality of sub-pixels of the substrate.

15. The display device of claim 14, wherein an arrangement density of the first transistor is greater than an arrangement density of the second transistor in the gate-in-panel.

16. The display device of claim 1, further comprising:
a first cover electrode as the fifth metal layer over the first source-drain electrode, the first cover electrode connected to the first source-drain electrode.

17. The display device of claim 1, wherein the second transistor is electrically connected to a light emitting element.

18. The display device of claim 17, wherein the light emitting element includes an anode, an intermediate layer, and a cathode,
wherein a second connection electrode as a sixth metal layer is between the anode and the second source-drain electrode, and the second connection electrode is the fifth metal layer.
